(19) United States
(12) Patent Application Publication
(10) Pub. No.: US 2012/0080737 A1
(43) Pub. Date: Apr. 5, 2012

(54) SEMICONDUCTOR DEVICE PROVIDED WITH A NON-VOLATILE MEMORY UNIT AND A MEMS SWITCH

(76) Inventors: Koichiro ZAITSU, Kanagawa-ken (JP); Shinichi Yasuda, Kanagawa-ken (JP); Shinobu Fujita, Tokyo (JP)

(21) Appl. No.: 13/051,834

(22) Filed: Mar. 18, 2011

(30) Foreign Application Priority Data
Sep. 30, 2010 (JP) P2010-223174

(51) Int. Cl. H01L 29/788

(52) U.S. Cl. 257/315; 257/E29.3

(57) ABSTRACT

According to one embodiment, a semiconductor device is provided. The semiconductor is provided with a MEMS switch element having a control terminal and a pair of signal terminals, and a non-volatile memory unit having first and second non-volatile semiconductor elements. The first non-volatile semiconductor element has a first source, a first drain and a first control gate terminal. The first drain is electrically connected to the control terminal of the MEMS switch element. The second non-volatile semiconductor element has a second source, a second drain and a second control gate terminal. The second drain gate terminal is electrically connected to the control terminal of the MEMS switch element.

### CROSS-REFERENCE TO RELATED APPLICATION(S)

This application is based upon and claims the benefit of priority from the prior Japanese Patent Application No. 2010-223174, filed on Sep. 30, 2010, the entire contents of which are incorporated herein by reference.

### FIELD

Embodiments described herein relate generally to a semiconductor device provided with a non-volatile memory unit and a MEMS (Micro Electro Mechanical Systems) switch.

### BACKGROUND

A programmable logic device (hereinafter referred to as “PLD”) allows a user to control logic information existing in an interior of an LSI, after the LSI is produced. Products such as field programmable gate arrays (hereinafter referred to as “FPGA”) are widely used as PLDs. The FPGA has switches and memory units for memorize logic information. A plurality of signal wirings is connected or disconnected by the switches according to the information stored in memory elements of the memory units so as to realize a logic circuit.

Instead of an SRAM as a memory element, an insulated gate field effect transistor having a floating gate electrode (hereinafter referred to as “FG transistor”) may be used in the FPGA. The FG transistor retains information even after the FPGA is turned off.

In a case that the FPGA has a structure provided with one switch and one FG transistor serving as a memory element, a control terminal for turning on and off the switch connected to the FG transistor may become in an electrically floating state when the FG transistor is in a high resistance state.

When the control terminal comes to be in the floating state, charges are accumulated in an electrode of the switch due to an unexpected leak current, etc. This may change the voltage of the electrode to cause operation error of the switch. Alternatively, when a certain signal is applied to another electrode in proximity to the electrode, the voltage of the control terminal changes due to a capacitive coupling between the electrodes to cause operation error of the switch.

### BRIEF DESCRIPTION OF THE DRAWINGS

FIG. 1 is a circuit diagram illustrating a representative portion of a semiconductor device according to a first embodiment.

FIGS. 2A to 2C are a cross sectional view, a plan view and a side view, respectively, which illustrate an example of a switch element capable of being used in the semiconductor device according to the first embodiment.

FIGS. 3A to 3C are a cross sectional view, a plan view and a side view, respectively, which illustrate another example of a switch element capable of being used in the semiconductor device according to the first embodiment.

FIG. 4 illustrates I-V characteristics of two FG transistors of the semiconductor device according to the first embodiment.

FIG. 5 is a circuit diagram illustrating a representative portion of a semiconductor device according to a second embodiment.

FIG. 6 illustrates I-V characteristics of two FG transistors of the semiconductor device according to the first embodiment.

FIG. 7 is a circuit diagram illustrating a representative portion of a semiconductor device according to a third embodiment.

FIG. 8 is a figure illustrating I-V characteristics of two FG transistors of the semiconductor device according to the third embodiment.

### DETAILED DESCRIPTION

According to one embodiment, a semiconductor device is provided. The semiconductor is provided with a MEMS (Micro Electro Mechanical Systems) switch element having a control terminal and a pair of signal terminals, and a non-volatile memory unit having first and second non-volatile semiconductor elements. The first non-volatile semiconductor element has a first source, a first drain and a first control gate terminal. The first drain is electrically connected to the control terminal of the MEMS switch element. The second non-volatile semiconductor element has a second source, a second drain and a second control gate terminal. The second drain gate terminal is electrically connected to the control terminal of the MEMS switch element.

According to another embodiment, a semiconductor device is provided. The semiconductor is provided with a MEMS switch element having a control terminal and a pair of signal terminals, and a non-volatile memory unit having first and second non-volatile semiconductor elements. The first non-volatile semiconductor element has a first source, a first drain and a first control gate terminal, the first drain is electrically connected to the control terminal of the MEMS switch element. The second non-volatile semiconductor element has a second source, a second drain and a second control gate terminal. The second drain gate terminal is electrically connected to the control terminal of the MEMS switch element. The first and the second control gate terminals are connected with each other.

Hereinafter, further embodiments will be described with reference to the drawings. In the drawings, the same reference numerals denote the same or similar portions respectively.

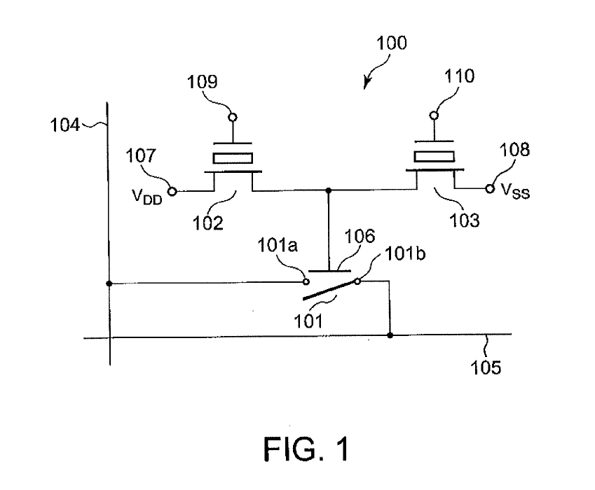

A semiconductor device according to a first embodiment will be explained below with reference to FIG. 1. FIG. 1 is a circuit diagram illustrating a representative portion of a semiconductor device according to the first embodiment. The semiconductor device is an FPGA.

The semiconductor device of FIG. 1 is provided with a switch element 101 and a memory unit 100 as basic constituent elements. In the embodiment, a MEMS switch is employed as the switch element 101. The memory unit 100 is provided with two FG transistors 102, 103. The FG transistor 102 is a first non-volatile semiconductor element. The FG transistor 103 is a second non-volatile semiconductor element.

The switch element 101 has two signal terminals 101a, 101b. The signal terminals 101a, 101b are connected to wirings 104, 105, respectively. By switching on or off the switch element 101, the wirings 104, 105 are allowed to be in a connection state or in a disconnection state. A voltage applied to the control terminal 106 enables switching on/off the switch element 101. The control terminal 106 is commonly connected to both of the drain terminals of the FG transistors 102, 103.

The FG transistors 102, 103 are programmed to operate according to input voltages applied to control gate terminals 109, 110, i.e., control gate electrodes, respectively. When one of the FG transistors 102, 103 is in a high resistance state, i.e., in an off state, the other of the FG transistors 102, 103 is in a low resistance state, i.e., in a on state. For example, when the FG transistor 102 is on, the FG transistor 103 is off. On the contrary, when the FG transistor 102 is off, the FG transistor 103 is on. Following the operation, the control terminal 106 of the switch element 101 is connected to a source terminal 107 or 108 via the FG transistor 102 or 103.

The source terminals 107, 108 of the FG transistors 102, 103 receive different voltages. For example, in the embodiment, a power supply voltage VDD is given to the terminal 107, and a ground voltage VSS is applied to the terminal 108. When the FG transistor 102 is on and the FG transistor 103 is off, the voltage of the control terminal 106 of the switch element 101 is determined by a resistance ratio of the FG transistors 102, 103. A voltage VM1 of the control terminal 106 is represented as follows. The on-resistance of the FG transistor 102 is expressed by “R1ON”, and the off-resistance of the FG transistor 103 is expressed by “R2OFF”.

VM1=(R1ON*VSS+R2OFF*VDD)/(R1ON+R2OFF)

Assume that the voltage necessary to turn on the switch element 101 is expressed by “VP” that is any voltage between VDD and VSS, the switch element 101 turns on when the voltage VM1 of the control terminal 106 is larger than the voltage VP.

When the FG transistors 102, 103 are programmed such that the FG transistor 102 is in an off-state and that the FG transistor 103 is in an on-state, the control terminal 106 of the switch element 101 is fixed at a voltage VM2 near VSS. The voltage VM2 is represented as follows by using an off-resistance R1OFF of the FG transistor 102 and an on-resistance R2ON of the FG transistor 103.

VM2=(R1OFF*VSS+R2ON*VDD)/(R1OFF+R2ON)

When the voltage VM2 is less than the voltage VP, the switch element 101 is in the off-state so that the wirings 104, 105 are not connected to each other.

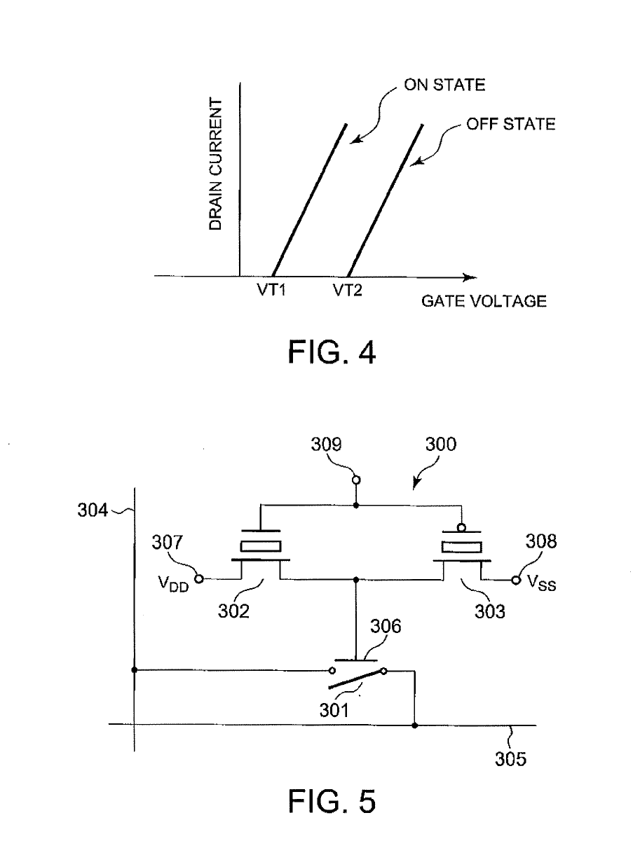

FIG. 4 illustrates characteristics of drain currents with respect to gate voltages (I-V characteristics) of two FG transistors 102, 103 of the semiconductor device according to the first embodiment.

As described above, the switch element 101 can be turned on and off according to the program states of the FG transistors 102, 103. The on/off states of the FG transistors 102, 103 are maintained even after the power is turned off. Accordingly, information as to whether the switch element 101 is turned on or off is maintained even after the power of the semiconductor device is turned off. Therefore, when the power is turned on again, the switch element 101 is turned on or off according to information stored in the FG transistors 102, 103.

The on/off state of the switch element 101 is determined only by an input from the control terminal 106. Thus, when the voltage of the control terminal 106 is more than the voltage VP, the switch element 101 is surely turned on. On the contrary, when the voltage of the control terminal 106 is less than the voltage VP, the switch element 101 has to be turned off surely.

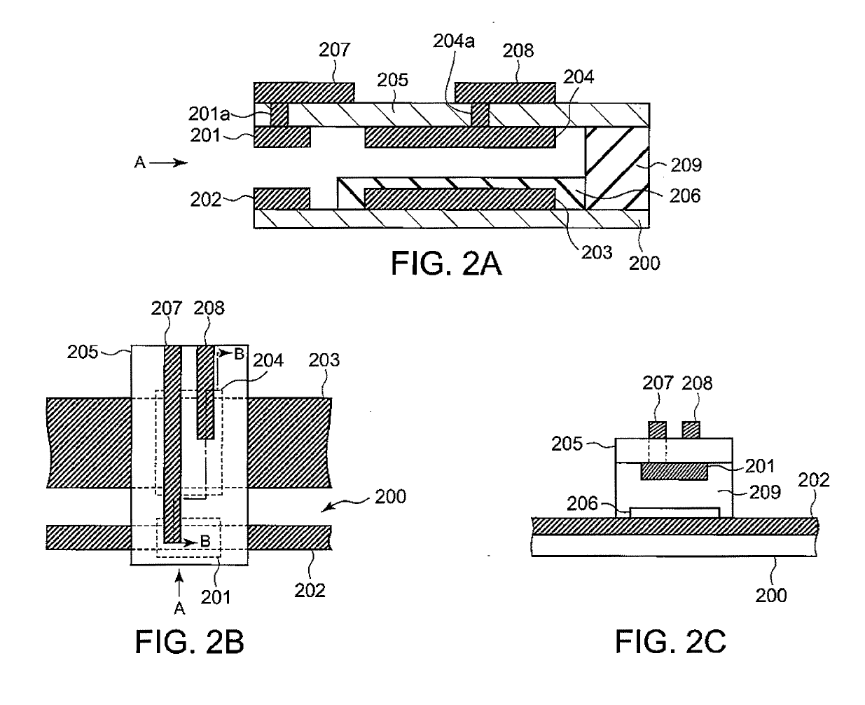

As will be explained in detail below, the switch element 101 provided in the embodiment is turned on/off by coulomb force generated between electrodes. FIGS. 2A to 2C illustrate an example of a detailed structure of the switch element 101. FIG. 2A is a cross sectional view illustrating the example. FIG. 2B is a plan view illustrating the example seen from above. FIG. 2A shows an enlarged view of a section B-B of FIG. 2B. FIG. 2C shows a side view of the example seen from direction A in of FIG. 2B. In FIGS. 2B and 2C, electrodes and wirings are diagonally shaded to make easy to discern the same.

In FIGS. 2A to 2C, the example of the switch element is provided with a fixed unit 200 having a flat-shape, a movable unit 205 having a flat-shape, electrodes 201 to 204, and wirings 207, 208. The electrodes 202, 203 are formed apart from each other on a surface of the fixed unit 200. The electrodes 201, 204 are formed apart from each other on one surface of the movable unit 205. The electrode 201 is connected to the wiring 207 formed on the other surface via an electrode 201a penetrating through a penetration hole formed in the movable unit 205. The electrode 204 is connected to a wiring 208 formed on the other surface via an electrode 204a penetrating through a penetration hole formed in the movable unit 205. The electrodes 207, 208 are formed apart from each other. A portion of the electrode 203 facing the movable unit 205 is covered with an insulating film 206. The movable unit 205 and the fixed unit 200 face each other with a distance provided between the units 200, 205 by a support member 209. The support member 209 is provided at end portions of the movable unit 205 and the fixed unit 200 in order to fix the units 200, 205 to the support member 209, as shown in FIGS. 2A to 2C. The fixed unit 200, the movable unit 205 and the support member 209 compose a bridge unit

When the switch element is on, the movable unit 205 is bent by coulomb force generated between the electrodes 203, 204. As a result, the electrodes 201, 202 come into contact with each other. When the switch element is off, the electrodes 201, 202 do not come into contact with each other.

One of the electrode 203 and the wiring 208 is connected to the control terminal 106 of FIG. 1, and the other is connected to another terminal having a fixed voltage. For example, the electrode 203 is connected to the control terminal 106 as the wiring, and the wiring 208 is connected to the ground voltage VSS.

The voltage of the electrode 204 is also fixed to be Vss. The on/off state of the switch element 101 is determined only by a voltage difference between the electrodes 203, 204. When the voltage of the electrode 204 changes, the on/off state of the switch element cannot be determined only by the signal inputted from the control terminal 106 to the electrode 203. Accordingly, change of the voltage of the electrode 204 is not desirable.

The electrodes 201, 202 are provided to correspond to the signal terminals 101a, 101b of the switch element 101 shown in FIG. 1, respectively. One of the wiring 207 and the electrode 202 is connected to the wiring 104 of FIG. 1. The other of the wiring 207 and the electrode 202 is connected to the wiring 105 of FIG. 1. When the switch element is on, the electrodes 201, 202 are in contact with each other so that the wirings 104, 105 of FIG. 1 are electrically connected with each other. On the contrary, when the switch element is off, the electrodes 201, 202 are separated from each other so that the wirings 104, 105 are electrically disconnected.

In the configuration of the switch element of FIGS. 2A to 2C, the on/off state of the switch element is determined only by the signal inputted to the control terminal 106 of FIG. 1, and is not influenced by the voltage of the wirings 104, 105. Thus, the switch element is prevented from causing error operation by an unexpected reason other than input to the control terminal 106.

The insulating film 206 is provided to cover the electrode 203. The insulating film 206 prevents direct contact between the electrode 203 and the electrode 204 due to coulomb force. Instead of providing the insulating film 206 to cover the electrode 203, an insulating film may be provided to cover the electrode 204, or insulating films may be provided to cover both of the electrodes 203, 204.

When the insulating film 206 is provided on the side of the movable unit 205, the Young's modulus of the entire movable unit may change. This may change the voltage VP of the switch element. Accordingly, in order to control the voltage VP, it is necessary to appropriately design the material, the film thickness, etc. of the insulating film 206 in view of parameters such as the Young's modulus.

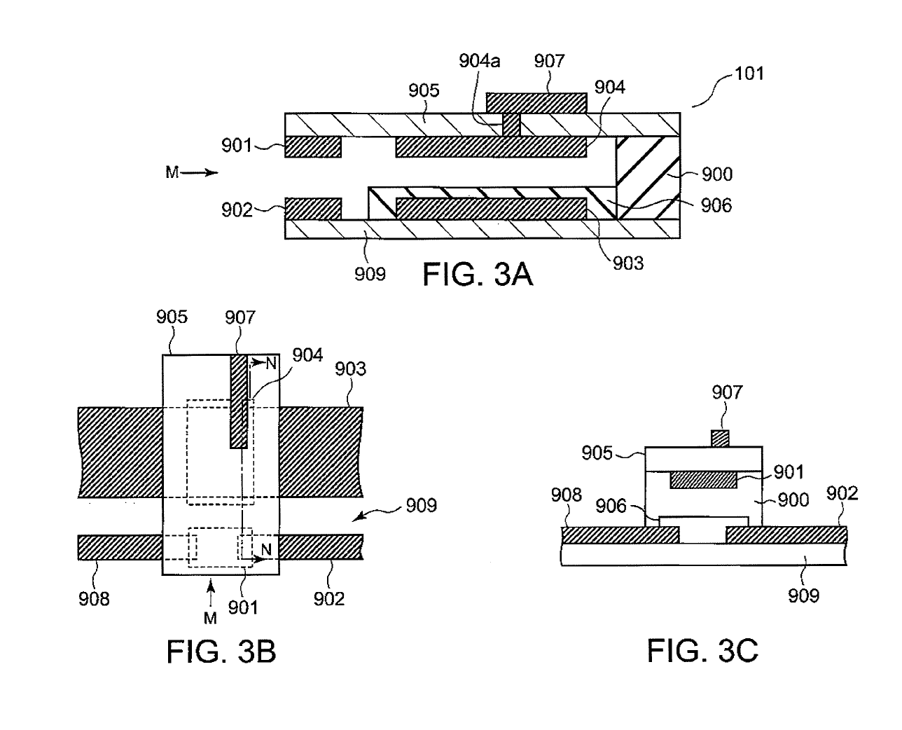

FIGS. 3A to 3C illustrate another example of a detailed structure of a switch element 101 of FIG. 1. FIG. 3A is a cross sectional view illustrating the example. FIG. 3B is a plan view illustrating the example seen from above. FIG. 3A enlarges a section N-N of FIG. 3B. FIG. 3C is a side view illustrating the example seen from a direction M. In FIGS. 3B and 3C, electrodes and wirings are diagonally shaded to discern the same.

In FIGS. 3A to 3C, the example of the switch element is provided with a fixed unit 909 having a flat-shape, a movable unit 905 having a flat-shape, electrodes 902 to 904, and 908, and wirings 907. The electrodes 902, 903, 908 are formed apart from each other on a surface of the fixed unit 909. The electrodes 901, 904 are formed apart from each other on one surface of the movable unit 905. The electrode 904 is connected to the wiring 907 formed on the other surface of the movable unit 905 via an electrode 904a which penetrates through a penetration hole formed in the movable unit 905. A portion of the electrode 903 facing the movable unit 905 is covered with an insulating film 906. The movable unit 905 and the fixed unit 909 are fixed to a support member 900 at end portions of the units 905, 909 with a distance provided between the units 905, 909. The fixed unit 909, the movable unit 905 and the support member 900A compose a bridge unit.

The switch element of FIGS. 3A to 3C is different from the example shown in FIGS. 2A to 2C in that any wiring is not connected to the electrode 901 and that end portions of the electrodes 902, 908 face each other. The electrodes 902, 908 are provided to correspond to the signal terminals 101a, 101b of the switch element 101 shown in FIG. 1, respectively. The movable unit 905 is bent by coulomb force generated between the electrodes 903, 904, and the movable unit 905 moves in a direction toward the fixed unit 909. As a result, the electrode 901 comes into contact with the electrodes 902, 908 so that the wirings 104, 105 of FIG. 1 are electrically connected to each other.

According to the first embodiment, the voltage of the control terminal 106 of the switch element 101 is fixed at VM1 or VM2 when the power supply voltages VSS, VDD are provided in FIG. 1. Thus, it is possible to prevent causing operation error of the switch element 101 by accumulation of charges to the electrodes of the switch element 101 due to an unexpected reason such as leak current, which occurs when the voltage of the control terminal 106 is in a floating state.

In a case that the switch element 101 and the memory unit 100 of the semiconductor device are formed on the same semiconductor substrate, the switch element 101 may be formed on a layer different from a layer provided with the FG transistors 102, 103. On the other hand, when a MOS transistor is provided instead of the switch element 101, the FG transistors and the MOS transistor need to be formed on the same layer. In this case, it is also necessary to provide a margin between an area for forming the FG transistors and an area for forming the MOS transistor, in order to separate the areas. Accordingly, the entire area size of the chip of the semiconductor device may be larger than that of a semiconductor chip provided with only MOS transistors or that of a semiconductor chip provided with only FG transistors.

In the first embodiment, as the FG transistors may be formed on the same well of a semiconductor substrate, the circuit area size of the semiconductor device can be reduced to a size smaller than that of a semiconductor device provided with an MOS transistor as the switch element.

Further, when a MOS transistor is employed in a semiconductor device instead of the switch element 101, the MOS transistor needs to be formed in a region apart from FG transistors. As a result, longer wirings need to be provided between the MOS transistor and the FG transistors, which reduces the operating speed of the semiconductor device. In the first embodiment, the switch element 101 can be formed on a layer above the FG transistors 102, 103, for example. Thus, shorter wirings may be provided between the switch element 101 and the FG transistors 102, 103 so that decrease of the operating speed can be prevented.

FIG. 5 is a circuit diagram illustrating a representative portion of a semiconductor device according to the second embodiment. The semiconductor device is an FPGA. As shown in FIG. 5, the semiconductor device is provided with a switch element 301 and a memory unit 300 as basic constituent elements. The memory unit 300 includes an N-channel FG transistor 302 and a P-channel FG transistor 303. The control gate terminals, i.e., control gate electrodes of both of the FG transistors 302, 303 are connected to a common terminal 309. A control terminal 306 of the switch element 301 is connected to drains of the FG transistors 302, 303. The signal terminals of the switch element 301 are connected to wirings 304, 305. A power supply voltage VDD or VSS is applied to source terminals 307, 308.

When a positive voltage VPROG1 is applied to the terminal 309, electrons are injected from a substrate into the floating gate of the FG transistor 302 and the floating gate of the FG transistor 303. Accordingly, both of the threshold voltages of the FG transistors 302, 303 shift in a positive direction. As a result, the FG transistor 302 turns off, and the FG transistor 303 turns on.

On the other hand, when a negative voltage VPROG2 is applied to the terminal 309, electrons move to the substrate from the floating gate of the FG transistor 302 and the floating gate of the FG transistor 303. Accordingly, both of the threshold voltages of the FG transistors 302, 303 shift in a negative direction. As a result, the FG transistor 302 turns on, and the FG transistor 303 turns off.

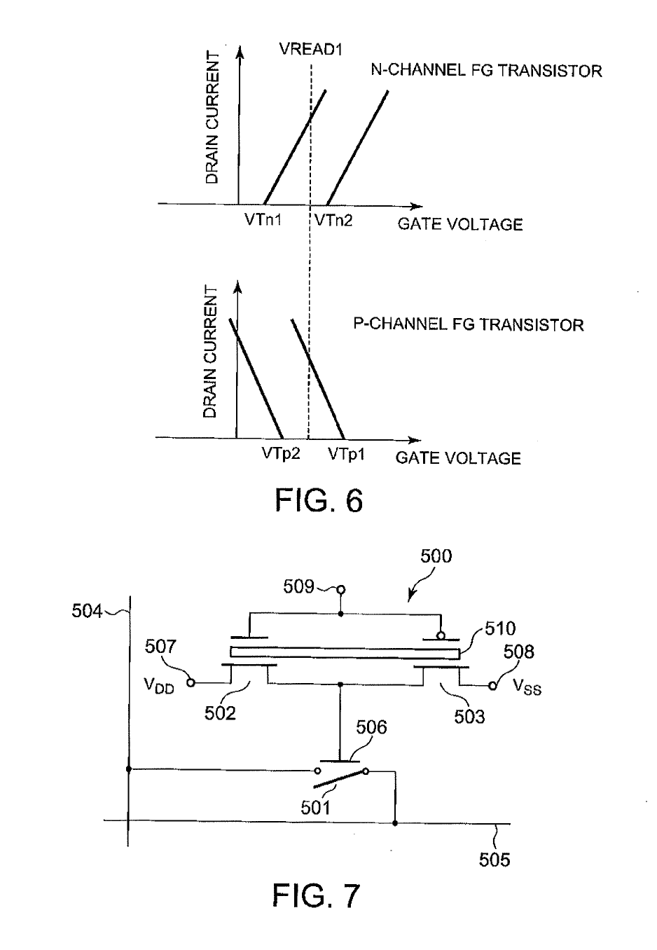

FIG. 6 illustrates characteristics of drain currents with respect to gate voltages (I-V characteristics) of the two transistors 302, 303 of the semiconductor device according to the second embodiment. Operation of the semiconductor device according to the second embodiment will be described with reference to FIG. 6.

The threshold voltage of the FG transistor 302 in an on-state is expressed by “VTn1”. The threshold voltage of the FG transistor 302 in an off-state is expressed by “VTn2”. The threshold voltage of the FG transistor 303 in an on-state is expressed by “VTp1”. The threshold voltage of the FG transistor 303 in an off-state is expressed by “VTp2”.

When a positive voltage VPROG1 is applied to the terminal 309, the threshold voltage of the FG transistor 302 changes from VTn1 to VTn2, and the threshold voltage of the FG transistor 303 changes from VTp2 to VTp1.

On the contrary, when a negative voltage VPROG2 is applied to the terminal 309, the threshold voltage of the FG transistor 302 changes from VTn2 to VTn1, and the threshold voltage of the FG transistor 303 changes from VTp1 to VTp2.

When the semiconductor device operates as the FPGA, a voltage VREAD1 is applied to the terminal 309. In the case, the voltage VREAD1 and the threshold voltages VTn1, VTn2, VTp1, VTp2 need to satisfy the following relationship.

VTn1<VREAD1<VTn2

VTp2<VREAD1<VTp1

Accordingly, the threshold voltages of the FG transistors 302, 303 need to be adjusted in advance by adjusting the impurity concentration of a semiconductor substrate or region where the FG transistor 302, 303 are formed. For example, each of the gate lengths of the FG transistors 302, 303 is assumed to be several dozen nanometers, and the reading voltage VREAD1 is assumed to be 0.5 V. In the case, it is estimated that the impurity concentration of a semiconductor substrate or region for forming the FG transistor 302 is preferably 1×10¹⁸ cm⁻³, and that the impurity concentration of a semiconductor substrate or region for forming the FG transistor 303 is preferably 1×10¹⁷ cm⁻³.

The power supply voltage VDD or VSS is applied to the source terminal 307, 308 of the FG transistor 302, 303. When the power supply voltage VDD is applied to the terminal 307, the ground voltage VSS is applied to the terminal 308. On the other hand, the voltage VSS may be applied to the terminal 307, and the power supply voltage VDD may be applied to the terminal 308.

A representative case will be explained below where the power supply voltage VDD is applied to the terminal 307 and the ground voltage VSS is applied to the terminal 308. The voltage applied to the terminal 309 is VREAD1. In the case, when the FG transistor 302 is in an off-state and the FG transistor 303 is in an on-state, the voltage of the control terminal 306 of the switch element 301 is near VSS and the switch element 301 is in an off-state. On the other hand, when the FG transistor 302 is in an on-state and the FG transistor 303 is in an off-state, the voltage of the control terminal 306 is raised to a level near VDD and the switch element 301 is turned on.

In the first embodiment, different input signals need to be applied to a gate terminals 109, 110 of the FG transistors 102, 103. Accordingly, in order to change resistance states of both of the FG transistor 102 and the FG transistor 103, the FG transistors 102, 103 need to be programmed one by one, which requires much time.

According to the second embodiment, the two FG transistors 302, 303 can be programmed by a signal inputted to the common terminal 309. Thus, the information retained in the FG transistors 302, 303 may be rewritten with one time input, which results in a higher rewriting speed.

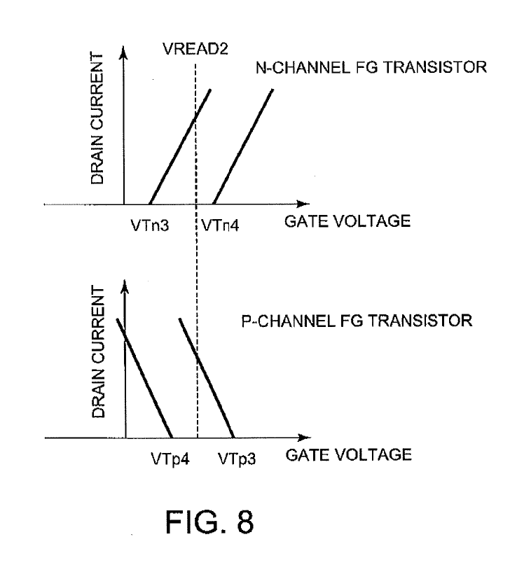

FIG. 7 is a circuit diagram illustrating a representative portion of a semiconductor device according to a third embodiment. FIG. 8 is a figure illustrating I-V characteristics of two FG transistors provided in the representative portion of the semiconductor device. The semiconductor device is an FPGA. As shown in FIG. 7, the semiconductor device is provided with a switch element 501 and a memory unit 500 as basic constituent elements. The memory unit 500 includes an N-channel FG transistor 502 and a P-channel FG transistor 503. The control gate terminals, i.e., control gate electrodes of both of the FG transistors 502, 503 are connected to a common terminal 509. The FG transistors 502, 503 are provided with a common floating gate 510. A control terminal 506 of the switch element 501 is connected to drains of the FG transistors 502, 503. Signal terminals of the switch element 501 are connected to wirings 504, 505 respectively. A power supply voltages VDD and VSS are applied to the source terminals 507, 508 respectively.

When a positive voltage VPROG3 is applied to the terminal 509, electrons are injected from a substrate into the common floating gate 510. Accordingly, both of the threshold voltages of the FG transistors 502, 503 shift in a positive direction. As a result, the FG transistor 502 turns off, and the FG transistor 503 turns on.

On the other hand, when a negative voltage VPROG4 is applied to the terminal 509, electrons move to the substrate from the common floating gate 510. Accordingly, both of the threshold voltages of the N-channel FG transistor 502 and the P-channel FG transistor 503 shift in a negative direction. As a result, the FG transistor 502 turns on, and the FG transistor 503 turns off.

Operation of the semiconductor device according to the third embodiment will be described with reference to FIG. 8. The threshold voltage of the FG transistor 502 in an on-state is expressed by “VTn3”. The threshold voltage of the FG transistor 502 in an off-state is expressed by “VTn4”. The threshold voltage of the FG transistor 503 in an on-state is expressed by “VTp3”. The threshold voltage of the FG transistor 503 in an off-state is expressed by “VTp4”.

When the positive voltage VPROG3 is applied to the terminal 509, the threshold voltage of the FG transistor 502 changes from VTn3 to VTn4, and the threshold voltage of the FG transistor 503 changes from VTp4 to VTp3.

On the contrary, when the negative voltage VPROG4 is applied to the terminal 509, the threshold voltage of the FG transistor 502 changes from VTn4 to VTn3, and the threshold voltage of the FG transistor 503 changes from VTp3 to VTp4.

When the semiconductor device shown in FIG. 7 operates as a FPGA, a voltage VREAD2 is applied to the terminal 509. In the case, the voltage VREAD2 and the threshold voltages VTn3, VTn4, VTp3, VTp4 need to satisfy the following relationship.

VTn3<VREAD2<VTn4

VTp4<VREAD2<VTp3

Thus, the impurity concentration of a semiconductor substrate or area for forming the FG transistor 502, 503 needs to be adjusted in advance so that the threshold voltages may be adjusted. For example, each of the gate lengths of the FG transistors 502, 503 is assumed to be several dozen nanometers, and a reading voltage VREAD2 is assumed to be 0.5 V. In the case, it is estimated that the impurity concentration of the semiconductor substrate or area for forming the FG transistor 502 is appropriately 1×10¹⁸ cm⁻³ and that the impurity concentration of the semiconductor substrate or area for forming the FG transistor 503 is appropriately 1×10¹⁷ cm⁻³.

When the power supply voltage VDD is applied to the terminal 507, the ground voltage VSS is applied to the terminal 508. The power supply voltage VSS may be applied to the terminal 507, and the power supply voltage VDD may be applied to the terminal 508.

A representative case will be described below where the power supply voltage VDD is applied to the terminal 507 and the ground voltage VSS is applied to the terminal 508. The voltage applied to the terminal 509 is VREAD2. In the case, when the FG transistor 502 is in an off-state, and the FG transistor 503 is in an on-state, the voltage of the control terminal 506 of the switch element 501 is near the ground voltage VSS, and the switch element 501 is still in an off-state. On the other hand, when the FG transistor 502 is in the on-state, and the FG transistor 503 is in an off-state, the voltage of the control terminal 506 is raised to a level near the power supply voltage VDD, and the switch element 501 is turned on.

According to the third embodiment, a channel of an inversion layer is formed in the FG transistor 502 when the voltage VPROG3 is applied to the terminal 509. Electrons are injected into the floating gate 510 from the source and drain diffusion layers of the transistor 502 via the inversion layer. The injected electrons modulate the threshold voltage of the FG transistor 502, and at the same time, the injected electrons diffuse in the floating gate 510, which may modulate the threshold voltage of the FG transistor 503.

A case may occur where the impurity concentration of the semiconductor substrate or area for forming the FG transistor 503 is small so that a sufficient quantity of electrons can not be provided to the floating gate 510 from the semiconductor substrate or area. In this case, it is difficult to modulate the threshold voltage of the FG transistor 503. According to the third embodiment, electrons can be provided to the floating gate 510 from the source and drain diffusion layers of the transistor 502. Thus, the threshold voltage of the FG transistor 503 can be modulated.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

For example, various kinds of non-volatile semiconductor elements may be used instead of the FG transistors.

What is claimed is:

1. A semiconductor device, comprising a MEMS switch element having a control terminal and a pair of signal terminals, and a non-volatile memory unit having first and second non-volatile semiconductor elements, wherein
The first non-volatile semiconductor element has a first source, a first drain and a first control gate terminal, the first drain being electrically connected to the control terminal of the MEMS switch element, and
The second non-volatile semiconductor element has a second source, a second drain and a second control gate terminal, the second drain gate terminal being electrically connected to the control terminal of the MEMS switch element.

2. The semiconductor device according to claim 1, wherein each of the first and second non-volatile semiconductor elements is a transistor having a floating gate electrode.

3. The semiconductor device according to claim 1, wherein the conductivity channel type of the first non-volatile semiconductor element is different form that of the second non-volatile semiconductor element, and signals provided to the first and the second control gates can be controlled independently.

4. The semiconductor device according to claim 1, wherein the MEMS switch element is provided with a bridge unit having first and second electrodes, and the bridge unit is bent by coulomb force controlled by the voltage of the control terminal so that the first and second electrodes can be brought into contact with each other or be separated from each other.

5. The semiconductor device according to claim 1, wherein the MEMS switch element is provided with a fixed unit, a movable unit, and a support member for supporting the fixed unit and the movable unit with a distance provided between the fixed unit and the movable unit,
wherein the fixed unit and the movable unit have first and second terminals serving as the signal terminals and facing each other, and the fixed unit and the movable unit have third and fourth electrodes respectively formed to be apart from the first and second electrodes and facing each other, the third electrode being covered with an insulating film.

6. The semiconductor device according to claim 1, wherein the MEMS switch element includes a fixed unit, a movable unit, and a support member for supporting the fixed unit and the movable unit with a distance provided between the fixed unit and the movable unit, and
wherein the fixed unit has first and second electrodes serving as the signal terminals and facing each other with a distance provided between the first and second electrodes, the movable unit has a third electrode facing at least end portions of the first and second electrodes which oppose to each other, the fixed unit and the movable unit have fourth and fifth electrodes respectively formed to be apart from the first, the second and third electrodes, the fourth electrode being covered with an insulating film.

7. A semiconductor device, comprising a MEMS switch element having a control terminal and a pair of signal terminals, and a non-volatile memory unit having first and second non-volatile semiconductor elements, wherein
The first non-volatile semiconductor element has a first source, a first drain and a first control gate terminal, the first drain being electrically connected to the control terminal of the MEMS switch element, and
The second non-volatile semiconductor element has a second source, a second drain and a second control gate terminal, the second drain gate terminal being electrically connected to the control terminal of the MEMS switch element, and wherein
the first and the second control gate terminals are connected with each other.

8. The semiconductor device according to claim 7, wherein each of the first and second non-volatile semiconductor elements is a transistor having a floating gate electrode structure.

9. The semiconductor device according to claim 7, wherein the MEMS switch element is provided with a bridge unit having first and second electrodes, and the bridge unit is bent by coulomb force controlled by the voltage of the control terminal so that the first and second electrodes can be brought into contact with each other or be separated from each other.

10. The semiconductor device according to claim 7, wherein the MEMS switch element is provided with a fixed unit, a movable unit, and a support member for supporting the fixed unit and the movable unit with a distance provided between the fixed unit and the movable unit,
wherein the fixed unit and the movable unit have first and second terminals serving as the signal terminals and facing each other, and the fixed unit and the movable unit have third and fourth electrodes respectively formed to be apart from the first and second electrodes and facing each other, the third electrode being covered with an insulating film.

11. The semiconductor device according to claim 7, wherein the MEMS switch element includes a fixed unit, a movable unit, and a support member for supporting the fixed unit and the movable unit with a distance provided between the fixed unit and the movable unit, and
wherein the fixed unit has first and second electrodes serving as the signal terminals and facing each other with a distance provided between the first and second electrodes, the movable unit has a third electrode facing at least end portions of the first and second electrodes which oppose to each other, the fixed unit and the movable unit have fourth and fifth electrodes respectively formed to be apart from the first, the second and third electrodes, the fourth electrode being covered with an insulating film.

12. The semiconductor device according to claim 8, wherein the first and second non-volatile semiconductor elements have a common charge accumulation layer serving as a floating gate electrode.

13. The semiconductor device according to claim 8, wherein the MEMS switch element is provided with a bridge unit having first and second electrodes, and the bridge unit is bent by coulomb force controlled by the voltage of the control terminal so that the first and second electrodes can be brought into contact with each other or be separated from each other.

14. The semiconductor device according to claim 8, wherein the MEMS switch element is provided with a fixed unit, a movable unit, and a support member for supporting the fixed unit and the movable unit with a distance provided between the fixed unit and the movable unit,
wherein the fixed unit and the movable unit have first and second terminals serving as the signal terminals and facing each other, and the fixed unit and the movable unit have third and fourth electrodes respectively formed to be apart from the first and second electrodes and facing each other, the third electrode being covered with an insulating film

15. The semiconductor device according to claim 8, wherein the MEMS switch element includes a fixed unit, a movable unit, and a support member for supporting the fixed unit and the movable unit with a distance provided between the fixed unit and the movable unit, and
wherein the fixed unit has first and second electrodes serving as the signal terminals and facing each other with a distance provided between the first and second electrodes, the movable unit has a third electrode facing at least end portions of the first and second electrodes which oppose to each other, the fixed unit and the movable unit have fourth and fifth electrodes respectively formed to be apart from the first, the second and third electrodes, the fourth electrode being covered with an insulating film.
